(19) United States
(12) Patent Application Publication
(10) Pub. No.: US 2022/0390848 A1
(43) Pub. Date: Dec. 8, 2022

(54) SUBSTRATE TREATING APPARATUS AND SUBSTRATE TREATING METHOD

(71) Applicant: SEMES CO., LTD., Cheonan-si (KR)

(72) Inventors: Ki Hoon CHOI, Cheonan-si (KR); Se Hoon OH, Cheonan-si (KR); Young Dae CHUNG, Incheon (KR); Tae Hee KIM, Yongin-si (KR); Young Eun JEON, Ulsan (KR)

(73) Assignee: SEMES CO., LTD., Cheonan-si (KR)

(21) Appl. No.: 17/834,154

(22) Filed: Jun. 7, 2022

(30) Foreign Application Priority Data
Jun. 8, 2021 (KR) 10-2021-0074359

(51) Int. Cl. G03F 7/30; G03F 7/20; G03F 7/42

(52) U.S. Cl. CPC G03F 7/30; G03F 7/70683; G03F 7/70025; G03F 7/707; G03F 7/422

(57) ABSTRACT

The present invention provides a substrate treating apparatus including: a support unit for supporting and rotating a substrate on which a first pattern and a second pattern different from the first pattern are formed; a liquid supply unit for supplying a treatment liquid to the substrate supported on the support unit; and a heating unit for heating any one of the first pattern and the second pattern.

### CROSS-REFERENCE TO RELATED APPLICATIONS

This application claims priority to and the benefit of Korean Patent Application No. 10-2021-0074359 filed in the Korean Intellectual Property Office on Jun. 8, 2021, the entire contents of which are incorporated herein by reference.

### TECHNICAL FIELD

The present invention relates to a substrate treating apparatus and a substrate treating method.

### BACKGROUND ART

In order to manufacture a semiconductor device, various processes, such as photography, etching, ashing, ion implantation, and thin film deposition, are performed on a substrate, such as a wafer. A variety of treatment liquids and treatment gases are used in each process. In addition, a drying process is performed on the substrate in order to remove the treatment liquid used for treating the substrate from the substrate.

The photography process for forming a pattern on a wafer includes an exposure process. The exposure process is a pre-operation for cutting a semiconductor integrated material adhered on the wafer into a desired pattern. The exposure process may have various purposes, such as forming a pattern for etching and forming a pattern for ion implantation. The exposure process draws a pattern with light on the wafer following a mask, which is a kind of ‘frame’. When light is emitted to a semiconductor integrated material on the wafer, such as a resist on the wafer, the chemical properties of the resist are changed according to the pattern by the light and the mask. When a developer is supplied to the resist whose chemical properties are changed according to the pattern, a pattern is formed on the wafer.

In order to precisely perform the exposure process, the above-described mask needs to be precisely manufactured. FIG. 1 is a diagram illustrating an example of a mask that may be used in an exposure process. Referring to FIG. 1, a plurality of alignment marks AK used when a mask M is aligned may be marked on the mask M that may be used in an exposure process. In addition, the mask M may have a plurality of cells C. In each cell C, a plurality of exposure patterns EP used to form a pattern on a substrate during an exposure process may be formed. In addition, each cell C may have a first pattern P1 that is a pattern for monitoring. In addition, a second pattern P2, which is a pattern for setting conditions of an exposure device performing an exposure process, may be formed in an area outside the cell C. When the exposure process is performed by using the mask M, in order for the exposure process to be precisely performed, it is preferable that a line width of the exposure pattern EP, a line width of the first pattern P1, and a line width of the second pattern P2 are the same.

When etching is performed to make the line width of the first pattern P1 and the line width of the second pattern P2 be equal to each other, over-etching may occur in the pattern. For example, a difference between an etching rate for the first pattern P1 and an the etching rate for the second pattern P2 may occur several times, and in order to reduce such the difference, over-etching may occur in the first pattern P1 and the second pattern P2 in the process of etching the first pattern P1 or the second pattern P2. When the etching process is precisely performed in order to minimize the occurrence of the over-etching, the etching process takes a lot of time. Accordingly, a line width correction process for precisely correcting the line widths of the patterns formed on the mask M is additionally performed.

FIG. 2 illustrates a normal distribution with respect to a first line width CDP1 of the first pattern P1 and a line width CDP2 of the second pattern P2 of the mask M before the line width correction process, which is the last operation of the mask M manufacturing process, is performed. In addition, the first line width CDP1 and the second line width CDP2 have sizes smaller than the target line widths. And, as can be seen with reference to FIG. 2, a deviation is intentionally placed in Critical Dimension (CD) of the first pattern P1 and the second pattern P2 before the line width correction process is performed.

In the linewidth correction process, an etching chemical liquid is supplied onto the substrate so that the first linewidth CDP1 and the second linewidth CDP2 become target linewidths. However, when the etching chemical liquid is uniformly supplied on the substrate, even if any one of the first line width CDP1 and the second line width CDP2 can reach the target line width, the other one of the first line width CDP1 and the second line width CDP2 is difficult to reach the target line width. Further, the deviation between the first line width CDP1 and the second line width CDP2 does not decrease. The mask M manufactured as described above makes it difficult to precisely perform an exposure process.

### SUMMARY OF THE INVENTION

The present invention has been made in an effort to provide a substrate treating apparatus and a substrate treating method, which are capable of efficiently treating a substrate.

The present invention has also been made in an effort to provide a substrate treating apparatus and a substrate treating method, which are capable of minimizing a treatment deviation of a pattern formed on a substrate.

The present invention has also been made in an effort to provide a substrate treating apparatus and a substrate treating method, which are capable of making line widths of patterns formed on a substrate be uniform.

The problem to be solved by the present invention is not limited to the above-mentioned problems, and the problems not mentioned will be clearly understood by those skilled in the art from the present specification and the accompanying drawings.

An exemplary embodiment of the present invention provides a substrate treating apparatus including: a support unit for supporting and rotating a substrate on which a first pattern and a second pattern different from the first pattern are formed; a liquid supply unit for supplying a treatment liquid to the substrate supported on the support unit; and a heating unit for heating any one of the first pattern and the second pattern.

According to the exemplary embodiment, the heating unit may include an emitting member for emitting light having thermal energy to the substrate; and a moving member for changing a position of the emitting member.

According to the exemplary embodiment, the emitting member may be configured such that the light emitted to the substrate is a laser.

According to the exemplary embodiment, the substrate treating apparatus may further include a controller for controlling the heating unit, the liquid supply unit, and the support unit, in which the controller may control the support unit so as not to rotate the substrate while the emitting member emits the light to the substrate.

According to the exemplary embodiment, the controller may control the support unit so as not to rotate the substrate while the liquid supply unit supplies an etching liquid to the substrate and control the support unit so as to rotate the substrate while the liquid supply unit supplies a cleaning liquid to the substrate.

According to the exemplary embodiment, the substrate treating apparatus may further include a controller for controlling the heating unit, the liquid supply unit, and the support unit, in which the heating unit may include an image acquiring member which acquires an image of at least one or more reference marks marked on the substrate, and transmits the acquired image to the controller, and the controller may derive substrate position information from the image and control the moving member so that the emitting member emits the light to any one of the first pattern and the second pattern based on the substrate position information and pattern position information, the pattern position information including position values of the first pattern and the second pattern in the substrate and being stored in advance in the controller.

According to the exemplary embodiment, the heating unit may further include a body in which the image acquiring member and the emitting member are installed and whose position is changed by driving force generated by the moving member.

According to the exemplary embodiment, the substrate treating apparatus may further include a controller for controlling the heating unit, the liquid supply unit, and the support unit, the controller may control the liquid supply unit to supply the treatment liquid onto the substrate to form a liquid film, and control the heating unit so as to heat the substrate in a state in which the liquid film is formed.

According to the exemplary embodiment, the substrate treating apparatus may further include a bowl having a treatment space in which the substrate is treated and providing a recovery path through which the treatment liquid is recovered, in which the support unit may be configured to support the substrate in the treatment space.

According to the exemplary embodiment, the support unit may include: a rotation shaft; a support plate coupled to the rotation shaft; and at least one support pin installed in the support plate and supporting an edge region of the substrate having a quadrangular shape.

According to the exemplary embodiment, the support pin may include: a first face supporting a lower portion of the substrate; and a second face facing a side portion of the substrate so as to limit a movement in a lateral direction of the substrate when the substrate is rotated.

Another exemplary embodiment of the present invention provides a substrate treating apparatus including: a support unit for supporting and rotating a substrate on which a first pattern and a second pattern performing a different function from a function of the first pattern are formed; a heating unit for heating the substrate; and a liquid supply unit for supplying an etching liquid to any one of the first pattern and the second pattern.

According to the exemplary embodiment, the liquid supply unit may include: a discharge unit for supplying the etching liquid in a form of droplets; and a moving unit for changing a position of the discharge unit.

According to the exemplary embodiment, the substrate treating apparatus may further include a controller for controlling the support unit, the heating unit, and the liquid supply unit, in which the liquid supply unit may include an image acquiring member which acquires an image of at least one or more reference marks marked on the substrate, and transmits the acquired image to the controller, and the controller may derive substrate position information from the image and control the moving member so that the discharge unit discharges the etching liquid to any one of the first pattern and the second pattern based on the substrate position information and pattern position information, the pattern position information including position values of the first pattern and the second pattern in the substrate and being stored in advance in the controller.

According to the exemplary embodiment, the controller may control the support unit so as not to rotate the substrate while the liquid supply unit supplies the etching liquid to the substrate.

According to the exemplary embodiment, the substrate treating apparatus may include: a rotation shaft having a hollow; a chuck stage coupled to the rotation shaft; and a window disposed above the chuck stage, in which the heating unit may include a heating unit disposed between the chuck stage and the window.

According to the exemplary embodiment, the heating unit may be an IR lamp or an LED lamp.

Another exemplary embodiment of the present invention provides a substrate treating method including: an etching operation of etching a substrate on which a first pattern and a second pattern different from the first pattern are formed; and a cleaning operation of cleaning the substrate, in which the etching operation includes (a) supplying an etching liquid to any one of the first pattern and the second pattern or (b) supplying an etching liquid onto the substrate and heating any one of the first pattern and the second pattern so that an etching rate of the first pattern and an etching rate of the second pattern are different from each other.

According to the exemplary embodiment in the operation (a), the first pattern and the second pattern may be heated, but the substrate may not be rotated while the etching liquid is supplied.

According to the exemplary embodiment in the operation (b), the substrate may not be rotated while any one of the first pattern and the second pattern is heated.

According to the exemplary embodiment of the present invention, it is possible to efficiently treat a substrate.

Further, according to the exemplary embodiment of the present invention, it is possible to minimize a treatment deviation of the pattern formed on the substrate.

Furthermore, according to the exemplary embodiment of the present invention, the line width of the pattern formed on the substrate may be made uniform.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram illustrating an example of a mask that may be used in an exposure process.

FIG. 2 is a diagram illustrating a normal distribution with respect to a line width of a first pattern and a line width of a second pattern of FIG. 1.

FIG. 3 is a top plan view schematically illustrating a substrate treating apparatus according to an exemplary embodiment of the present invention.

FIG. 4 is a diagram schematically illustrating an exemplary embodiment of the substrate treating apparatus provided in a liquid treating chamber of FIG. 3.

FIG. 5 is a diagram of a support unit and a mask of FIG. 4 viewed from above.

FIG. 6 is a diagram illustrating a substrate treating method according to an exemplary embodiment of the present invention.

FIG. 7 is a diagram illustrating an example of supplying a treating liquid to a substrate in an etching operation of FIG. 5.

FIG. 8 is a diagram illustrating an example of an image acquired by an image acquiring member before a pattern formed on a substrate is heated in the etching operation of FIG. 5.

FIG. 9 is a diagram illustrating a state in which the pattern formed on the substrate is heated in the etching operation of FIG. 5.

FIG. 10 is a diagram illustrating a state in which a treatment liquid is supplied to the substrate in a cleaning operation of FIG. 5.

FIG. 11 is a diagram schematically illustrating another exemplary embodiment of a substrate treating apparatus provided in the liquid treating chamber of FIG. 3.

FIG. 12 is a diagram illustrating another example of supplying the treatment liquid to the substrate in the etching operation of FIG. 5.

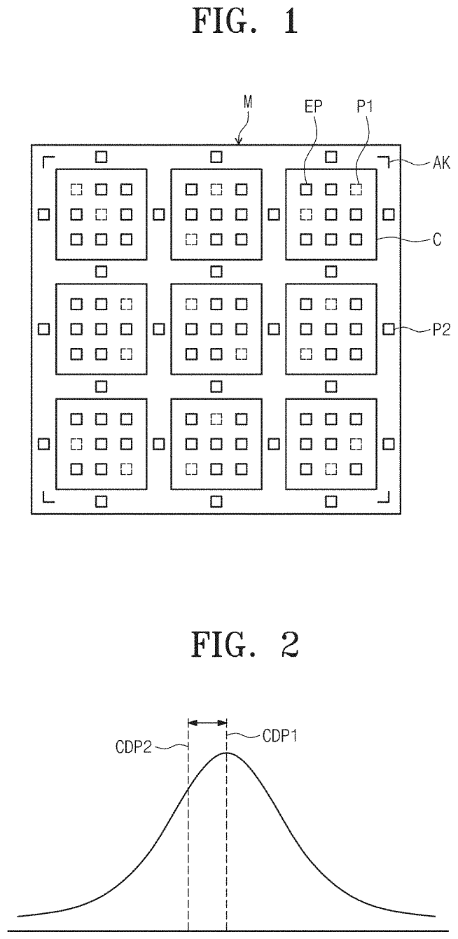

### DETAILED DESCRIPTION

Hereinafter, an exemplary embodiment of the present invention will be described more fully hereinafter with reference to the accompanying drawings, in which exemplary embodiments of the invention are shown. However, the present invention can be variously implemented and is not limited to the following embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “comprise” and variations such as “comprises” or “comprising” will be understood to imply the inclusion of stated elements but not the exclusion of any other elements. It will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between” and “just between” or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

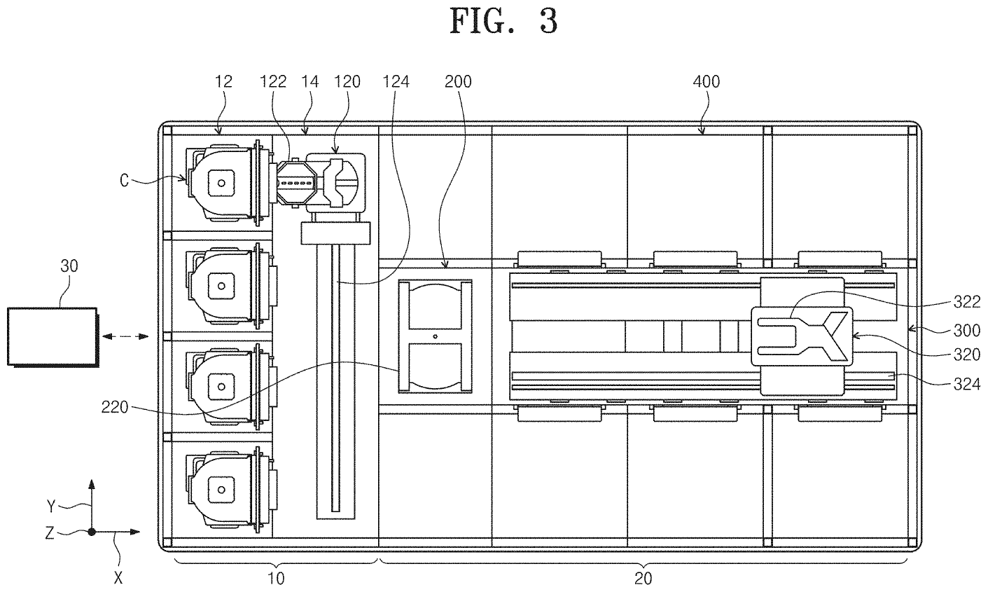

Hereinafter, an exemplary embodiment of the present invention will be described with reference to FIGS. 3 to 12.

FIG. 3 is a top plan view schematically illustrating a substrate treating apparatus according to an exemplary embodiment of the present invention.

Referring to FIG. 3, the substrate treating apparatus includes an index module 10, a treating module 20, and a controller 30. When viewed from above, the index module 10 and the treatment module 20 are disposed along one direction. Hereinafter, the direction in which the index module 10 and the treatment module 20 are arranged is referred to as a first direction X, when viewed from above, a direction perpendicular to the first direction X is referred to as a second direction Y, and a direction perpendicular to both the first direction X and the second direction Y is referred to as a third direction Z.

The index module 10 transfers a substrate M from a container C in which the substrate M is accommodated to the treatment module 20, and transfers the substrate M that has been completely treated in the treatment module 20 to the container C. A longitudinal direction of the index module 10 is provided in the second direction Y. The index module 10 includes a load port 12 and an index frame 14. Based on the index frame 14, the load port 12 is located at a side opposite to the treating module 20. The container C in which the substrates M are accommodated is placed on the load port 12. A plurality of load ports 12 may be provided, and the plurality of load ports 12 may be disposed along the second direction Y.

As the container C, an airtight vessel, such as a Front Open Unified Pod (FOUP), may be used. The container C may be placed on the load port 12 by a transport means (not illustrated), such as an overhead transfer, an overhead conveyor, or an automatic guided vehicle, or an operator.

An index robot 120 is provided to the index frame 14. A guide rail 124 of which a longitudinal direction is provided in the second direction Y is provided in the index frame 14, and the index robot 120 may be provided to be movable on the guide rail 124. The index robot 120 includes a hand 122 on which the substrate M is placed, and the hand 122 may be provided to be movable forward and backward, rotatable about the third direction Z, and movable along the third direction Z. The plurality of hands 122 is provided while being spaced apart from each other in the vertical direction, and is capable of independently moving forward and backward.

The controller 30 may control the substrate treating apparatus. The controller 30 may include a process controller formed of a microprocessor (computer) that executes the control of the substrate treating apparatus, a user interface formed of a keyboard in which an operator performs a command input operation or the like in order to manage the substrate treating apparatus, a display for visualizing and displaying an operation situation of the substrate treating apparatus, and the like, and a storage unit storing a control program for executing the process executed in the substrate treating apparatus under the control of the process controller or a program, that is, a treatment recipe, for executing the process in each component according to various data and treatment conditions. Further, the user interface and the storage unit may be connected to the process controller. The treatment recipe may be stored in a storage medium in the storage unit, and the storage medium may be a hard disk, and may also be a portable disk, such as a CD-ROM or a DVD, or a semiconductor memory, such as a flash memory.

The controller 30 may control the substrate treatment apparatus so as to perform a substrate treatment method to be described below. For example, the controller 30 may control configurations provided to a liquid treating chamber 400 to perform the substrate treatment method described below.

The treatment module 20 includes a buffer unit 200, a transfer chamber 300, and a liquid treating chamber 400. The buffer unit 200 provides a space in which the substrate M loaded to the treatment module 20 and the substrate M unloaded from the treatment module 20 temporarily stay. The liquid treating chamber 400 performs a liquid treatment process of liquid-treating the substrate M by supplying a liquid onto the substrate M. The transfer chamber 300 transfers the substrate M between the buffer unit 200, the liquid treating chamber 400, and a drying chamber 500.

A longitudinal direction of the transfer chamber 300 may be provided in the first direction X. The buffer unit 200 may be disposed between the index module 10 and the transfer chamber 300. The liquid treating chamber 400 and the drying chamber 500 may be disposed on the side of the transfer chamber 300. The liquid treating chamber 400 and the transfer chamber 300 may be disposed along the second direction Y. The drying chamber 500 and the transfer chamber 300 may be disposed along the second direction Y. The buffer unit 220 may be positioned at one end of the transfer chamber 300.

According to an example, the liquid treating chambers 400 may be disposed on both sides of the transfer chamber 300. At one side of the transport chamber 300, the liquid treating chambers 400 may be provided in an arrangement of A×B (each of A and B is 1 or a natural larger than 1) in the first direction X and the third direction Z.

The transfer chamber 300 has a transfer robot 320. A guide rail 324 of which a longitudinal direction is provided in the first direction X is provided in the transfer chamber 300, and the transfer robot 320 may be provided to be movable on the guide rail 324. The transfer robot 320 includes a hand 322 on which the substrate M is placed, and the hand 322 may be provided to be movable forward and backward, rotatable about the third direction Z, and movable along the third direction Z. A plurality of hands 322 are provided to be spaced apart in the vertical direction, and the hands 322 may move forward and backward independently of each other.

The buffer unit 200 includes a plurality of buffers 220 on which the substrate M is placed. The buffers 220 may be disposed to be spaced apart from each other along the third direction Z. A front face and a rear face of the buffer unit 200 are opened. The front face is a face facing the index module 10 and the rear face is a face facing the transfer chamber 300. The index robot 120 may approach the buffer unit 200 through the front face, and the transport robot 320 may approach the buffer unit 200 through the rear face.

Hereinafter, the substrate treating apparatus provided in the liquid treating chamber 400 will be described in detail. An object to be processed in the liquid treating chamber 400 may be a substrate of any one of a wafer, glass, and a photomask. Hereinafter, the present invention will be described based on a photo mask that is a “frame” used in the exposure process of the substrate M treated in the liquid treating chamber 400 as an example. Further, the present invention will be described based on the case where a Fine Critical Dimension Correction (FCC) that is the last operation in a manufacturing process of a mask for an exposure process is performed as an example.

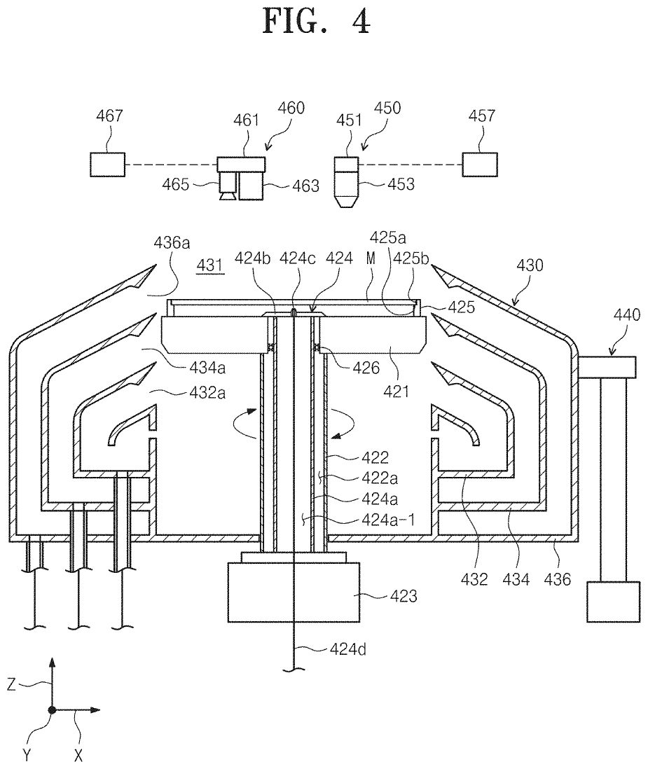

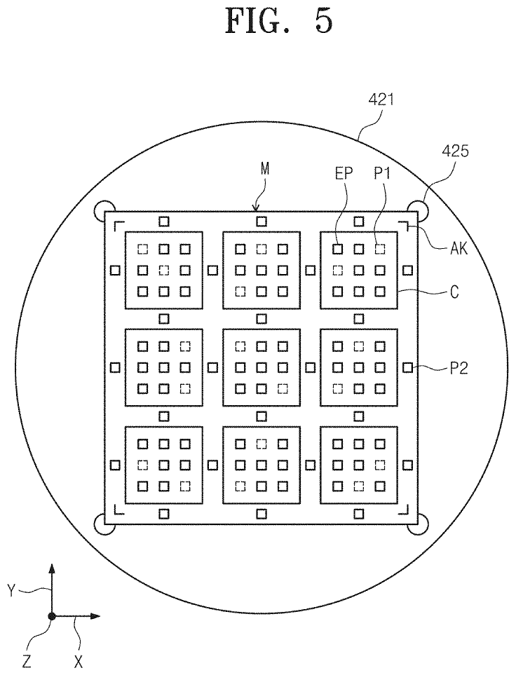

FIG. 4 is a diagram schematically illustrating an exemplary embodiment of the substrate treating apparatus provided in the liquid treating chamber of FIG. 3, and FIG. 5 is a diagram of the support unit and the mask of FIG. 4 viewed from above.

With reference to FIG. 5, a substrate M which is a to-be-treated object will be described. The substrate M may have a quadrangular shape. The substrate M may be a photomask that is a ‘frame’ used during an exposure process. At least one reference mark AK may be marked on the substrate M. The reference mark AK may be a mark used for aligning the substrate M, called an alignment key. Further, the reference mark AK may be a mark used to derive position information of the substrate M. For example, an image acquiring member 465 described later may acquire an image by photographing the reference mark AK, and transmit the acquired image to the controller 30. The controller 30 may analyze the image including the reference mark AK to detect an exact position of the substrate M. Further, the reference mark AK may also be used or recognizing a position of the substrate M when the substrate M is transferred.

A cell C may be formed on the substrate M. At least one cell C, for example, a plurality of cells C may be formed. A plurality of patterns may be formed in each cell C. The pattern formed in the cell C may include an exposure pattern EP and a first pattern P1. The exposure pattern EP may be used to form an actual pattern on the substrate M. The first pattern P1 may be a pattern for monitoring that allows it to be checked whether light emission using the exposure pattern EP is properly performed in the exposure process. The first pattern P1 may also be referred to as a critical dimension monitoring macro. The second pattern P2 may be a pattern for setting conditions used when an exposure device is set up. The second pattern P2 may also be referred to as an anchor pattern.

The substrate M that is loaded into the liquid treating chamber 400 and treated may be a substrate M that has been pre-treated. Line widths of the first pattern P1 and the second pattern P2 of the substrate M loaded into the liquid treating chamber 400 may be different from each other. For example, the line width of the first pattern P1 may be a first width (for example, 69 nm). The line width of the second pattern P2 may be a second width (for example, 68.5 nm).

The substrate treating apparatus provided in the liquid treating chamber 400 according to the exemplary embodiment of the present invention will be described with reference to FIGS. 4 and 5. The substrate treating apparatus provided in the liquid treating chamber 400 may include a support unit 420, a bowl 430, a lifting unit 440, a liquid supply unit 450, and a heating unit 460.

The support unit 420 may support the substrate M in a treatment space 431 of the bowl 430, which will be described later. The support unit 420 may support the substrate M. The support unit 420 may rotate the substrate M. The support unit 420 may include a support plate 421, a rotation shaft 422, a rotation actuator 423, a lower fluid supply unit 424, a support pin 425, and a bearing 426.

The support plate 421 may have a plate shape. The support plate 421 may provide an area in which the support pins 425 supporting the substrate M may be installed. The support plate 421 may be rotated by being coupled to the rotation shaft 422. When viewed from the top, an opening into which the lower fluid supply unit 424, which is to be described later, is inserted may be formed in the central region of the support plate 421. The opening may be formed so as to extend from an upper portion to a lower portion of the support plate 421. That is, the opening formed in the central region of the support plate 421 may be formed through the support plate 421.

The rotation shaft 422 may be a hollow shaft having a hollow space 422a. The rotation shaft 422 may be coupled to the support plate 421. The rotation shaft 422 may receive a driving force from a rotation driver 423 which is a hollow motor to rotate the support plate 421. The lower fluid supply unit 424 may be inserted into the hollow space 422a of the rotation shaft 422.

The lower fluid supply unit 424 may supply a treatment fluid to the lower portion of the substrate M. The treatment fluid may be a treatment liquid or treatment gas. The treatment fluid supplied to the lower portion of the substrate M may include a chemical or a rinse solution. The chemical may be a liquid having acid or basic properties. Chemicals may include sulfuric acid, phosphoric acid, hydrofluoric acid, and ammonium hydroxide. The rinse liquid may be pure water. The treatment gas may be inert gas. The treatment gas may also dry the lower portion of the substrate M.

The lower fluid supply unit 424 may include a hollow shaft 424a, a cover 424b, a fluid discharge unit 424c, and a fluid supply line 424d. The hollow shaft 424a may have a hollow region 424a-1 therein. At least a portion of the fluid supply line 424d to be described later may be provided in the hollow region 424a-1. The hollow shaft 424a may be independent of rotation of the rotation shaft 422 and the support plate 421. The hollow shaft 424a may be inserted into the hollow space 422a of the rotation shaft 422 and the opening of the support plate 421. The hollow shaft 424a may be provided to be spaced apart from the rotation shaft 422 and the support plate 421. A bearing 426 may be provided in a space where the hollow shaft 424a and the support plate 421 face each other.

The cover 424b may be installed above the hollow shaft 424a. The cover 424b may prevent the treatment liquid supplied to the substrate M from flowing into the hollow space 422a or the hollow region 424a-1. The cover 424b may be provided with a fluid discharge unit 424c that is fluidly connected to the fluid supply line 424d transferring the treatment fluid. The fluid discharge unit 424c may have a tubular shape.

The support unit 425 may support the substrate M. The support pin 425 may be installed on the support plate 421. The support pin 425 may have a generally circular shape when viewed from above. Also, when viewed from above, the support pin 425 may have a shape in which a portion corresponding to the edge region of the substrate M is depressed in a downward direction. That is, the support pin 425 includes a first surface 425a supporting the lower portion of the edge region of the substrate M, and a second surface 425b facing the side of the edge region of the substrate M so as to limit the movement in the lateral direction of the substrate M when the substrate M is rotated. At least one support pin 425 may be provided. A plurality of support pins 425 may be provided. The support pins 425 may be provided in a number corresponding to the number of edge regions of the substrate M having a quadrangular shape. The support pins 425 support the substrate M to separate the lower surface of the substrate M and the upper surface of the support plate 421. In addition, the support pin 425 may be configured to make a distal end of the fluid discharge unit 424c of the lower fluid supply part 424 and the lower surface of the substrate M be spaced apart from each other.

The bowl 430 may have a cylindrical shape having an open top. The bowl 430 has a treatment space 431, and the substrate M may be liquid-treated and heat-treated in the treatment space 431. The lifting unit 440 adjusts the relative height between the bowl 430 and the substrate M supported by the support unit 420.

According to an example, the bowl 430 has a plurality of recovery containers 432, 424, and 426. Each of the recovery containers 432, 424, and 426 has a recovery space of recovering the liquid used for the treatment of the substrate. Each of the recovery containers 432, 424, and 426 is provided in a ring shape surrounding the support unit 440. When the liquid treatment process is in progress, the treatment liquid scattered by the rotation of the substrate M is introduced into the recovery spaces through inlets 432a, 424a, and 426a of the recovery containers 432, 424, 426. According to an example, the bowl 430 has a first recovery container 432, a second recovery container 434, and a third recovery container 436. The first recovery container 432 is disposed to surround the support unit 440, the second recovery container 434 is disposed to surround the first recovery container 432, and the third recovery container 436 is disposed to surround the second recovery container 434. The second inlet 434a through which the liquid is introduced to the second recovery container 434 may be positioned above the first inlet 432a through which the liquid is introduced to the first recovery container 432, and the third inlet 436a through which the liquid is introduced to the third recovery container 436 may be positioned above the second inlet 434a.

The liquid supply unit 450 may supply the treatment liquid for liquid treating the substrate M. The treatment liquid may be an etching liquid, a cleaning liquid, or a rinse liquid. The etching liquid may be a chemical. The etching liquid may be supplied to the substrate M in an etching operation S20 to be described later. The etching liquid may etch the pattern formed on the substrate M. The etching liquid may also be referred to as an etchant. The cleaning liquid or the rinse liquid may clean the substrate M. After the cleaning liquid is supplied, the rinse liquid may be supplied to the substrate M. The cleaning solution or the rinsing solution may be provided as a known chemical solution.

The liquid supply unit 450 may include a first body 451, a nozzle 453, and a first moving member 457. A nozzle 453 may be installed on the first body 451. The position of the first body 451 may be changed by receiving a driving force from the first moving member 457, so that a position thereof may be changed. The position of the first body 451 may be changed along the first direction X and/or the second direction Y. In some cases, the position of the first body 451 may also be changed along the third direction Z. The first body 451 may be an arm or a guide body moving along a rail. The type of the first body 451 may be variously modified into a known shape in which the nozzle 453 is installed and the driving force is transmitted from the first moving member 457. The nozzle 453 may supply at least one of the above-described treatment liquids. In addition, a plurality of nozzles 453 may be provided, and the cleaning liquid, rinsing liquid, and etching liquid described above may be respectively discharged from each nozzle 453.

The heating unit 460 may heat the substrate M supported on the support unit 420. For example, the heating unit 460 may be configured to heat any one of the first pattern P1 and the second pattern P2 of the substrate M. For example, the heating unit 460 may be configured to heat the second pattern P2 between the first pattern P1 and the second pattern P2.

The heating unit 460 may include a second body 461, an emitting member 463, an image acquiring member 465, and a second moving member 467. The emitting member 463 and the image acquiring member 465 may be installed on the second body 461. The position of the second body 461 may be changed by receiving the driving force of the second moving member 467. For example, the position of the second body 461 may be changed along the first direction X and/or the second direction Y. In some cases, the position of the second body 461 may also be changed along the third direction Z. The second body 461 may be an arm or a guide body moving along a rail. The type of the second body 461 may be variously modified into a known device in which the emitting member 463 and/or the image acquiring member 465 are installed, and the driving force is transmitted from the second moving member 467.

The emitting member 463 may emit light having thermal energy to the substrate M. The width of the light emitted by the emitting member 463 may have a very fine width. For example, the emitting member 463 may be configured to emit a laser L.

The image acquiring member 465 may be installed on the second body 461 and move together with the emitting member 463. The image acquiring member 465 may acquire an image of the upper surface of the substrate M. The image acquiring member 465 may acquire an image of the substrate M and transmit the acquired image to the controller 30. The image acquiring member 465 may be a member acquiring an image. The image acquiring member 465 may be a camera.

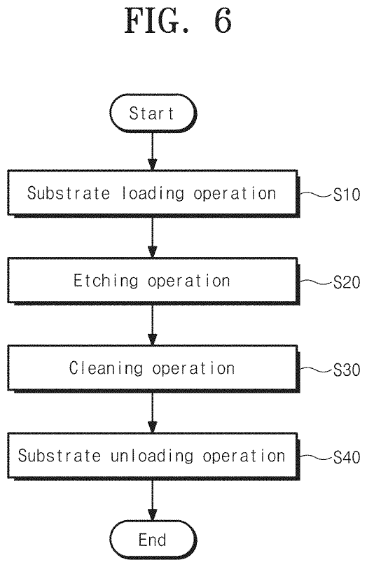

FIG. 6 is a diagram illustrating a substrate treating method according to an exemplary embodiment of the present invention. Referring to FIG. 6, the substrate treatment method according to the exemplary embodiment of the present invention may include a substrate loading operation S10, an etching operation S20, a cleaning operation S30, and a substrate unloading operation S40.

The substrate loading operation S10 may be an operation of loading the substrate M into the liquid treating chamber 400 to support the substrate M on the support unit 420.

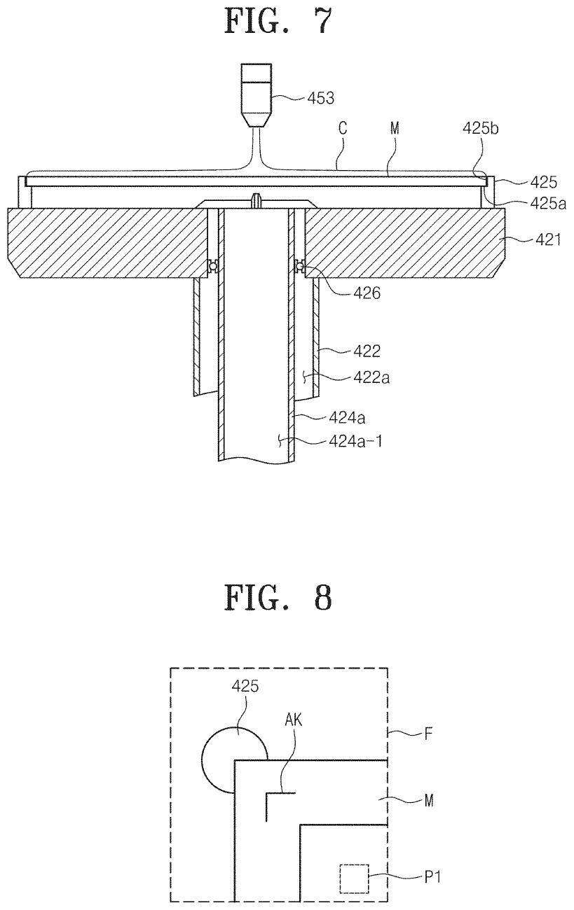

The etching operation S20 may be an operation in which the liquid supply unit 450 supplies an etching liquid, for example, a chemical C, to the substrate M. The etching operation S20 may be an FCC process for correcting the line width difference between the first pattern P1 and the second pattern P2 described above. In the etching operation S20, the support unit 420 may not rotate the substrate M. In the etching operation, the liquid supply unit 450 may supply the chemical C, which is an etching liquid, to the center of the substrate M which is not rotated (see FIG. 7). The nozzle 453 of the liquid supply unit 450 may not move, and may supply the etching liquid to the central region of the substrate M. The etching liquid supplied to the central region of the substrate M may be diffused and cover the entire upper surface of the substrate M. In addition, the liquid supply unit 450 may supply a relatively small amount of the etching liquid so that the etching liquid covers the entire upper surface of the substrate M, but and the amount of etching liquid flowing down is not large. If necessary, the etching liquid may also be supplied to the entire upper surface of the substrate M while the nozzle 453 changes its position.

Then, the image acquiring member 465 of the heating unit 460 may acquire an image of the substrate M. For example, the image acquiring member 465 may acquire an image of the reference mark AK marked on the substrate M (see FIG. 8). The image acquiring member 465 may acquire at least one image of the reference mark AK. The image acquiring member 465 may acquire an image of the reference mark AK while the position thereof is changed, and the image acquiring member 465 may be moved upward to capture a wider range to acquire images of the reference marks AK at once. The image captured by the image acquiring member 465 may be transmitted to the controller 30.

The controller 30 may derive position information of the substrate M from the image. For example, the controller 30 may analyze the received image to derive exactly which position of the substrate M is supported and the range of the treatment area required to be treated on the substrate M. In addition, location information for the patterns may be previously stored in the controller 30. The position information of the patterns may include information about position values of the first pattern P1, the second pattern P2, and the exposure pattern EP in the substrate M. That is, the controller 30 may specify the position of the second pattern P2, which is a region requiring local heating by accurately deriving the position of the substrate M from the image transmitted by the image acquiring member 465 (that is, deriving the position information of the substrate), and combining the derived substrate position information and the pre-stored pattern position information with each other.

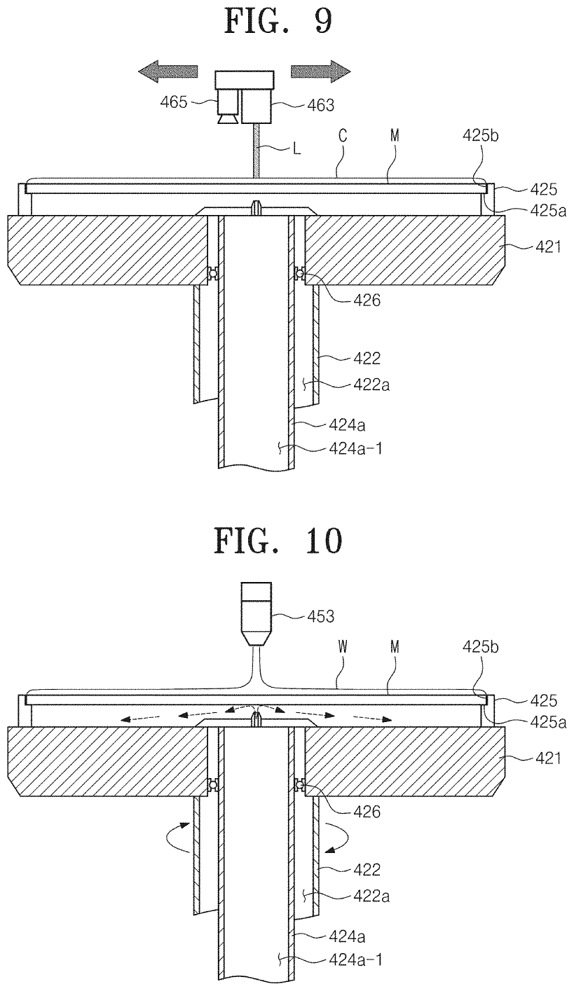

The heating unit 460 may emit light, such as the laser L, to a selected pattern among the patterns of the substrate M having a liquid film formed on the entire area of the substrate M by the etching liquid (see FIG. 9). For example, the heating unit 460 may emit the laser L to any one of the first pattern P1 and the second pattern P2. For example, the heating unit 460 may emit a laser to the second pattern P2 between the first pattern P1 and the second pattern P2. In this case, the emission position of the laser L may be specified by a control value calculated by the controller 30 based on the above-described substrate position information and pattern position information.

In addition, since the laser L needs to be emitted to a partial region on the substrate M (for example, the region in which the second pattern P2 is formed in the substrate M), so that the substrate M is not rotated and its position may be fixed while the heating unit 460 emits the laser L in the etching operation S20. In the etching operation S20, the etching liquid is supplied to the entire area of the substrate M, and the laser L is emitted only to a portion of the area of the substrate M (for example, the area where the second pattern P2 is formed), the temperature of the substrate M in the region where the second pattern P2 is formed increases. Accordingly, the etching ability of the etching liquid for the second pattern P2 is improved. Therefore, the line width of the first pattern P1 may be changed from the first width (for example, 69 nm) to the target line width (for example, 70 nm). Further, the line width of the second pattern P2 may be changed from the second width (for example, 68.5 nm) to the target line width (for example, 70 nm). That is, by improving the etching ability of the partial region of the substrate M, it is possible to minimize the deviation of the line width of the pattern formed on the substrate M.

Also, when the etching operation S20 is performed, process byproducts may be generated on the substrate M. In addition, process by-products may enter the lower region of the substrate M. In some cases, the etching liquid supplied to the substrate M may enter the lower region of the substrate M. Accordingly, after the etching operation S20, the cleaning operation S30 may be performed. In the cleaning operation S30 performed after the etching operation S20, the support unit 420 may rotate the substrate M, the liquid supply unit 450 supplies the cleaning liquid W to the upper portion of the rotating substrate M, and the lower fluid supply unit 424 may supply the treatment fluid to the lower portion of the substrate M.

When the treatment of the substrate M is completed, the substrate unloading operation S40 of unloading the substrate M from the liquid treatment chamber 400 may be performed.

In the above-described example, the case where after supplying the etching liquid to the entire region of the substrate M, the partial region of the substrate M is heated through the laser L has been described as an example, but the present invention is not limited thereto. For example, after laser L emission is performed first, the etching liquid may be supplied.

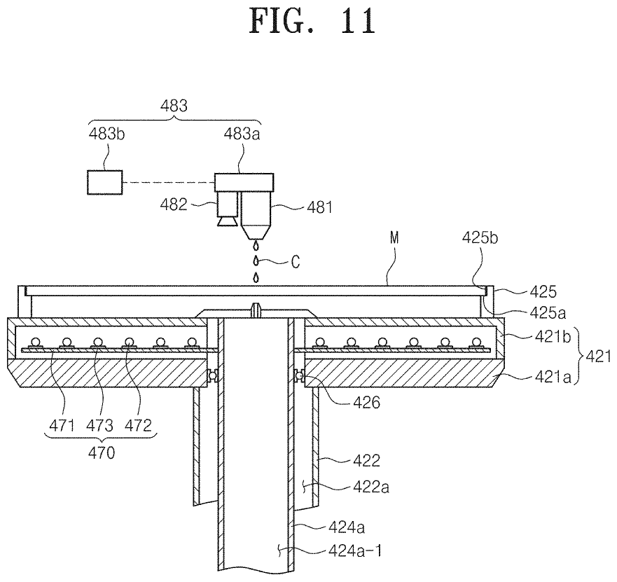

In the above-described example, the case where after supplying the etching liquid to the entire region of the substrate M, the partial region of the substrate M is heated through the laser L has been described as an example, but the present invention is not limited thereto. For example, the entire area of the substrate M may be heated and the etching liquid may be supplied to a partial area of the substrate M. For example, as shown in FIG. 11, the heating unit 470 may be disposed within the support plate 421. For example, the support plate 421 may include a chuck stage 421a coupled to the rotation shaft 422 to rotate, and a quartz window 421b disposed on the chuck stage 421a. The chuck stage 421a and the quartz window 421b may be combined with each other to form an inner space, and the heating unit 470 may be disposed in the inner space. The heating unit 470 may include a reflective plate 471 coupled with the hollow shaft 424a and independent from the rotation of the rotation shaft 422a, a heating unit 472, and a temperature control unit 473 for controlling the heating unit 472 that is fixedly installed on the reflective plate 471 to generate heat. The heating unit 472 may be an IR lamp or an LED lamp.

The liquid supply unit 480 may include a discharging unit 481, an image acquiring unit 482, and a moving unit 483. The discharge unit 481 may be a head of an inkjet module capable of discharging the etching liquid that is the chemical C in the form of droplets. The image acquisition unit 482 may perform a function similar to that of the image acquiring member 465. For example, the image acquisition unit 482 may help the etching liquid discharged from the discharge unit 481 to be discharged to a partial area of the substrate M, for example, an area in which the second pattern P2 of the substrate M is formed. The moving unit 483 may include a moving body 483a and a moving driver 483b. The moving unit 483 may move the position of the discharge unit 481 in the first direction X and/or the second direction Y. According to another exemplary embodiment of the present invention, the entire region of the substrate M may be heated by the heating unit 470, and the etching liquid may be supplied to only a partial region of the region of the substrate M. Accordingly, the FCC process may be performed on the partial region of the substrate M. In addition, since the etching liquid needs to be supplied to only the partial region of the substrate M, the substrate M may not be rotated while the liquid supply unit 480 supplies the etching liquid.

That is, according to the exemplary embodiment of the present invention, the etching liquid is supplied to the entire area of the substrate M and either one of the first pattern P1 and the second pattern P2 is heated so that an etch rate of the first pattern P1 and an etch rate of the second pattern P2 are different from each other. In addition, according to another exemplary embodiment of the present invention, the entire area of the substrate M is heated and the etching liquid is supplied to any one of first pattern P1 and the second pattern P2 so that the etching rate of the first pattern P1 and the etching rate of the second pattern P2 are different from each other.

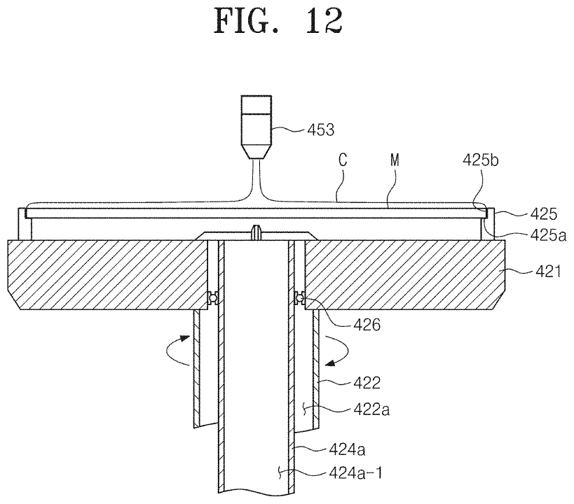

In the above-described example, the case where the substrate M is not rotated while the liquid supply unit 450 supplies the etching liquid in the etching operation S20 has been described as an example, but the present invention is not limited thereto. For example, as illustrated in FIG. 12, the substrate M may also be rotated while the liquid supply unit 450 supplies the etching liquid in the etching operation S20.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A substrate treating apparatus, comprising:
a support unit for supporting and rotating a substrate on which a first pattern and a second pattern different from the first pattern are formed;
a liquid supply unit for supplying a treatment liquid to the substrate supported on the support unit; and
a heating unit for heating any one of the first pattern and the second pattern.

2. The substrate treating apparatus of claim 1, wherein the heating unit includes:
an emitting member for emitting light having thermal energy to the substrate; and
a moving member for changing a position of the emitting member.

3. The substrate treating apparatus of claim 2, wherein the emitting member is configured such that the light emitted to the substrate is a laser.

4. The substrate treating apparatus of claim 2, further comprising:
a controller for controlling the heating unit, the liquid supply unit, and the support unit;
wherein the controller controls the support unit so as not to rotate the substrate while the emitting member emits the light to the substrate.

5. The substrate treating apparatus of claim 4, wherein the controller controls the support unit so as to rotate the substrate while the liquid supply unit supplies a cleaning liquid to the substrate.

6. The substrate treating apparatus of claim 2, further comprising:
a controller for controlling the heating unit, the liquid supply unit, and the support unit,
wherein the heating unit includes an image acquiring member which acquires an image of at least one or more reference marks marked on the substrate, and transmits the acquired image to the controller, and
the controller derives substrate position information from the image and controls the moving member so that the emitting member emits the light to any one of the first pattern and the second pattern based on the substrate position information and pattern position information, the pattern position information including position values of the first pattern and the second pattern in the substrate and being stored in advance in the controller.

7. The substrate treating apparatus of claim 6, wherein the heating unit further includes a body in which the image acquiring member and the emitting member are installed and whose position is changed by driving force generated by the moving member.

8. The substrate treating apparatus of claim 2, further comprising:
a controller for controlling the heating unit, the liquid supply unit, and the support unit,
wherein the controller controls the liquid supply unit to supply the treatment liquid onto the substrate to form a liquid film, and controls the heating unit so as to heat the substrate in a state in which the liquid film is formed.

9. The substrate treating apparatus of claim 1, further comprising:
a bowl having a treatment space in which the substrate is treated and providing a recovery path through which the treatment liquid is recovered,
wherein the support unit is configured to support the substrate in the treatment space.

10. The substrate treating apparatus of claim 1, wherein the support unit includes:
a rotation shaft;
a support plate coupled to the rotation shaft; and
at least one support pin installed in the support plate and supporting an edge region of the substrate having a quadrangular shape.

11. The substrate treating apparatus of claim 10, wherein
the support pin includes:
a first face supporting a lower portion of the substrate; and
a second face facing a side portion of the substrate so as to limit a movement in a lateral direction of the substrate when the substrate is rotated.

12. A substrate treating apparatus, comprising:
a support unit for supporting and rotating a substrate on which a first pattern and a second pattern performing a different function from a function of the first pattern are formed;
a heating unit for heating the substrate; and
a liquid supply unit for supplying an etching liquid to any one of the first pattern and the second pattern.

13. The substrate treating apparatus of claim 12, wherein the liquid supply unit includes:
a discharge unit for supplying the etching liquid in a form of droplets; and
a moving unit for changing a position of the discharge unit.

14. The substrate treating apparatus of claim 13, further comprising:
a controller for controlling the support unit, the heating unit, and the liquid supply unit;
wherein the liquid supply unit includes an image acquiring member which acquires an image of at least one or more reference marks marked on the substrate, and transmits the acquired image to the controller, and
the controller derives substrate position information from the image and controls the moving member so that the discharge unit discharges the etching liquid to any one of the first pattern and the second pattern based on the substrate position information and pattern position information, the pattern position information including position values of the first pattern and the second pattern in the substrate and being stored in advance in the controller.

15. The substrate treating apparatus of claim 14, wherein the controller controls the support unit so as not to rotate the substrate while the liquid supply unit supplies the etching liquid to the substrate.

16. The substrate treating apparatus of claim 12, further comprising:
a rotation shaft having a hollow;
a chuck stage coupled to the rotation shaft; and
a window disposed above the chuck stage,
wherein the heating unit includes a heating unit disposed between the chuck stage and the window.

17. The substrate treating apparatus of claim 16, wherein the heating unit is an IR lamp or an LED lamp.

18. A substrate treating method, comprising:
an etching operation of etching a substrate on which a first pattern and a second pattern different from the first pattern are formed; and
a cleaning operation of cleaning the substrate,
wherein the etching operation includes (a) supplying an etching liquid to any one of the first pattern and the second pattern or (b) supplying an etching liquid onto the substrate and heating any one of the first pattern and the second pattern so that an etching rate of the first pattern and an etching rate of the second pattern are different from each other.

19. The substrate treating method of claim 18, wherein in the operation (a), the first pattern and the second pattern are heated, but the substrate is not rotated while the etching liquid is supplied.

20. The substrate treating method of claim 18, wherein in the operation (b), the substrate is not rotated while any one of the first pattern and the second pattern is heated.

1. A substrate treating apparatus, comprising:
a support unit for supporting and rotating a substrate on which a first pattern and a second pattern different from the first pattern are formed;
a liquid supply unit for supplying a treatment liquid to the substrate supported on the support unit; and
a heating unit for heating any one of the first pattern and the second pattern.

2. The substrate treating apparatus of claim 1, wherein the heating unit includes:
an emitting member for emitting light having thermal energy to the substrate; and
a moving member for changing a position of the emitting member.

3. The substrate treating apparatus of claim 2, wherein the emitting member is configured such that the light emitted to the substrate is a laser.

4. The substrate treating apparatus of claim 2, further comprising:
a controller for controlling the heating unit, the liquid supply unit, and the support unit;
wherein the controller controls the support unit so as not to rotate the substrate while the emitting member emits the light to the substrate.

5. The substrate treating apparatus of claim 4, wherein the controller controls the support unit so as to rotate the substrate while the liquid supply unit supplies a cleaning liquid to the substrate.

6. The substrate treating apparatus of claim 2, further comprising:
a controller for controlling the heating unit, the liquid supply unit, and the support unit,
wherein the heating unit includes an image acquiring member which acquires an image of at least one or more reference marks marked on the substrate, and transmits the acquired image to the controller, and
the controller derives substrate position information from the image and controls the moving member so that the emitting member emits the light to any one of the first pattern and the second pattern based on the substrate position information and pattern position information, the pattern position information including position values of the first pattern and the second pattern in the substrate and being stored in advance in the controller.

7. The substrate treating apparatus of claim 6, wherein the heating unit further includes a body in which the image acquiring member and the emitting member are installed and whose position is changed by driving force generated by the moving member.

8. The substrate treating apparatus of claim 2, further comprising:
a controller for controlling the heating unit, the liquid supply unit, and the support unit,
wherein the controller controls the liquid supply unit to supply the treatment liquid onto the substrate to form a liquid film, and controls the heating unit so as to heat the substrate in a state in which the liquid film is formed.

9. The substrate treating apparatus of claim 1, further comprising:
a bowl having a treatment space in which the substrate is treated and providing a recovery path through which the treatment liquid is recovered,
wherein the support unit is configured to support the substrate in the treatment space.

10. The substrate treating apparatus of claim 1, wherein the support unit includes:
a rotation shaft;
a support plate coupled to the rotation shaft; and
at least one support pin installed in the support plate and supporting an edge region of the substrate having a quadrangular shape.

11. The substrate treating apparatus of claim 10, wherein
the support pin includes:
a first face supporting a lower portion of the substrate; and
a second face facing a side portion of the substrate so as to limit a movement in a lateral direction of the substrate when the substrate is rotated.

12. A substrate treating apparatus, comprising:
a support unit for supporting and rotating a substrate on which a first pattern and a second pattern performing a different function from a function of the first pattern are formed;
a heating unit for heating the substrate; and
a liquid supply unit for supplying an etching liquid to any one of the first pattern and the second pattern.

13. The substrate treating apparatus of claim 12, wherein the liquid supply unit includes:
a discharge unit for supplying the etching liquid in a form of droplets; and
a moving unit for changing a position of the discharge unit.

14. The substrate treating apparatus of claim 13, further comprising:
a controller for controlling the support unit, the heating unit, and the liquid supply unit;
wherein the liquid supply unit includes an image acquiring member which acquires an image of at least one or more reference marks marked on the substrate, and transmits the acquired image to the controller, and
the controller derives substrate position information from the image and controls the moving member so that the discharge unit discharges the etching liquid to any one of the first pattern and the second pattern based on the substrate position information and pattern position information, the pattern position information including position values of the first pattern and the second pattern in the substrate and being stored in advance in the controller.

15. The substrate treating apparatus of claim 14, wherein the controller controls the support unit so as not to rotate the substrate while the liquid supply unit supplies the etching liquid to the substrate.

16. The substrate treating apparatus of claim 12, further comprising:
a rotation shaft having a hollow;
a chuck stage coupled to the rotation shaft; and
a window disposed above the chuck stage,
wherein the heating unit includes a heating unit disposed between the chuck stage and the window.

17. The substrate treating apparatus of claim 16, wherein the heating unit is an IR lamp or an LED lamp.

18-20. (canceled)
